(19) United States
(12) Patent Application Publication
(10) Pub. No.: US 2025/0358929 A1
(43) Pub. Date: Nov. 20, 2025

(54) CONNECTION CIRCUIT AND METHOD OF MANUFACTURING CONNECTION CIRCUIT

(71) Applicant: Yazaki Corporation, Tokyo (JP)

(72) Inventor: Masafumi WATANABE, Shizuoka (JP)

(73) Assignee: Yazaki Corporation, Tokyo (JP)

(21) Appl. No.: 19/198,343

(22) Filed: May 5, 2025

(30) Foreign Application Priority Data
May 14, 2024 (JP) 2024-078564

(51) Int. Cl. H05K 1/02; H05K 3/00

(52) U.S. Cl. CPC H05K 1/028; H05K 3/005

(57) ABSTRACT

A connection circuit includes a base material, and circuits printed on the base material with conductive ink, in which a part of the base material is folded; at least parts of the circuits are layered in a vertical direction in a plan view; and the base material is interposed between the circuits in the vertical direction.

### CROSS-REFERENCE TO RELATED APPLICATIONS

The present application is based on, and claims priority from the prior Japanese Patent Application No. 2024-078564, filed on May 14, 2024, the entire contents of which are incorporated herein by reference.

### TECHNICAL FIELD

The present disclosure relates to a connection circuit, and a method of manufacturing a connection circuit.

### BACKGROUND

In recent years, there has been a requirement for flexible printed circuit boards (FPCs) that can achieve miniaturized, thin, and three-dimensional wire harnesses and their peripheral parts due to a decrease in wiring space of automobiles. In particular, thinner sensor modules with FPCs, which are capable of detecting the current of cells, are required for controlling a mounted battery with progress in electrification of automobiles.

In order to meet the demand for miniaturization, thinness, and three-dimensionality, printed circuit boards are required that have higher degrees of freedom in circuit formation than FPCs, and that can be manufactured at a lower cost. In the printed circuit boards described above, a conductive layer is formed by printing a conductive material made of conductive ink or conductive paste, such as silver or copper, on a flexible base material made of a thin and soft resin film having electrical insulation properties, using a printing method such as screen printing. For example, JP 2010-272837 A discloses fabrication of a substrate for a printed circuit board by printing conductive ink, in which metal particles are dispersed, on an insulating base material made of a film or sheet.

### SUMMARY OF THE INVENTION

However, the substrate for a printed circuit board base material disclosed in JP2010-272837 A has the following problems: the degrees of freedom in circuit formation are low, and complex circuit formation, such as a twisted structure, is difficult due to circuits formed on the same layer. In addition, design and manufacturing processes are complex, and noise occurs between parallel circuits when a multi-layered structure is used.

The present disclosure has been made in view of such problems in the conventional technology. It is an object of the present disclosure to provide a connection circuit which can be simply produced by using conductive ink, thereby increasing the degrees of freedom in circuit formation and improving noise resistance; and a method of manufacturing a connection circuit.

A connection circuit according to the present embodiment includes a base material having electrical insulation properties, and circuits printed on the base material with conductive ink, in which a part of the base material is folded, at least parts of the circuits are layered in a vertical direction in a plan view, and the base material is interposed between the circuits in the vertical direction in a side view.

A method of manufacturing a connection circuit according to the present embodiment provides a method of manufacturing a connection circuit including a base material having electrical insulation properties, and circuits printed on the base material with conductive ink, including: a step of printing circuits on the base material with conductive ink; a step of punching out a part of the base material so that the base material includes joint parts, and a plurality of divided base materials connected by the joint parts; and a step of folding and arranging the joint parts so that at least parts of circuits printed on the plurality of divided base materials are layered in a vertical direction in a plan view, and interposing the base material between the circuits in the vertical direction in a side view.

According to the present disclosure, it is possible to provide a connection circuit which can be simply produced by using conductive ink, thereby increasing the degrees of freedom in circuit formation and improving noise resistance; and a method of manufacturing a connection circuit.

### BRIEF DESCRIPTION OF DRAWINGS

FIG. 1A is a schematic view illustrating an example of circuits printed on a base material.

FIG. 1B is a schematic view illustrating a state of the base material illustrated in FIG. 1A after being punched and divided.

FIG. 1C is a top view illustrating a connection circuit after the base material illustrated FIG. 1B is folded.

FIG. 2A is a schematic view illustrating an example of circuits printed on a base material.

FIG. 2B is a schematic view illustrating a state of the base material illustrated in FIG. 2A after being punched and divided.

FIG. 2C is a top view of a connection circuit after the base material illustrated in FIG. 2B is folded.

FIG. 3 is a side view illustrating a state of the base material illustrated in FIG. 1B or FIG. 2B after being folded.

FIG. 4 is a side view illustrating a connection circuit after the base material illustrated in FIG. 3 is compressed in a vertical direction.

FIG. 5A is a schematic view illustrating an example of a circuit printed on the base material.

FIG. 5B is a schematic view illustrating a state of the base material illustrated in FIG. 5A after being punched and divided.

FIG. 5C is a top view of the connection circuit after the base material illustrated in FIG. 5B is folded.

### DETAILED DESCRIPTION OF THE INVENTION

Hereinafter, a connection circuit and a method of manufacturing a connection circuit according to the present embodiment will be described in detail with reference to the drawings. The dimensional ratios in the drawings are exaggerated for the sake of explanation, and may differ from the actual ratios.

### Connection Circuit

### First Embodiment

A connection circuit 40 according to the present embodiment includes a base material 10 having electrical insulation properties, and circuits 20 printed on the base material 10 with conductive ink. The circuits 20 are printed by applying conductive ink to the base material 10 in a desired shape and then baking. The circuits 20 have one or more conductor patterns formed to extend in a longitudinal direction of the base material 10.

Known conductive ink can be used to configure the circuits 20. The conductive ink includes a conductive filler, a binder, an organic solvent, and the like. The conductive ink is applied to the base material, and then baked to form a conductor, thereby enabling electrical connection. Examples of the conductive filler contained in the conductive ink include a carbon component or a metal component. The carbon component preferably contains at least one selected from the group consisting of carbon black, graphite, graphene, carbon nanotubes, and carbon fibers. The metal component preferably contains at least one selected from the group consisting of gold, silver, copper, platinum, palladium, rhodium, ruthenium, iridium, osmium, tungsten, nickel, tantalum, bismuth, lead, indium, tin, zinc, and titanium.

The method for printing the conductive ink on the base material 10 is not particularly limited, and conventionally known methods such as screen printing, rotary screen printing, flexographic printing, inkjet printing, gravure printing, gravure offset printing, offset printing, or the like, can be adopted. Printing by screen printing is preferable due to possibility of production in large quantities and at low cost.

Examples of the base material 10 which can be used for the circuits 20 may include a film, sheet, or plate material having electrical insulation properties. The base material 10 is flexible, and can be folded according to locations to be used. Examples of materials for the base material 10 may include at least one selected from the group consisting of polyimide (PI), polyethylene terephthalate (PET), polyethylene naphthalate (PEN), polycarbonate (PC), polypropylene (PP), and polybutylene terephthalate (PBT).

In the connection circuit 40 according to the present embodiment, a part of the base material 10 is folded, as described below. In the connection circuit 40, at least parts of the circuits 20 are layered in a vertical direction in a plan view, and the base material 10 is interposed between the circuits 20 in the vertical direction in a side view.

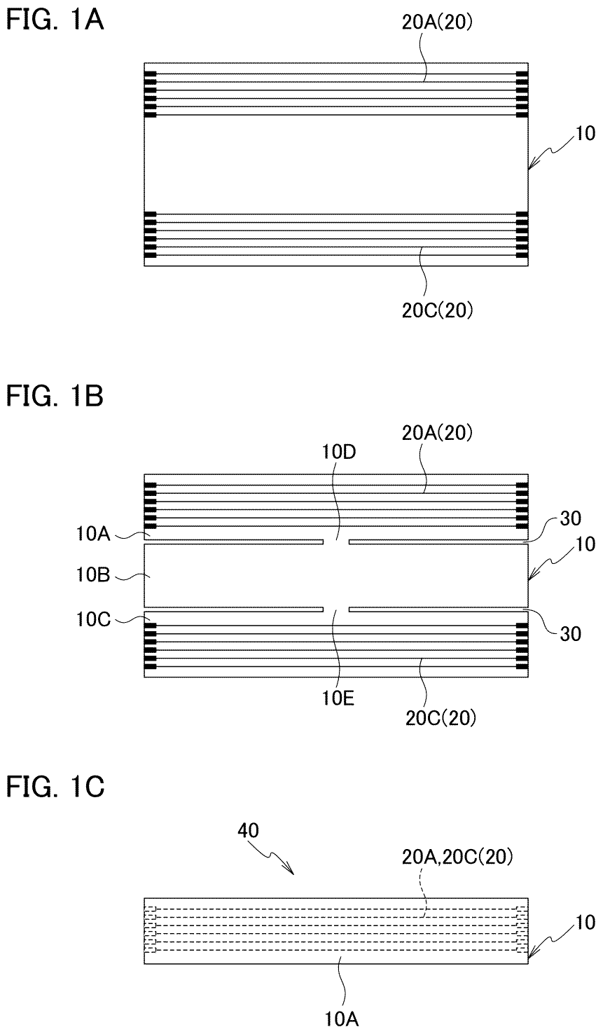

The base material 10 may have joint parts 10D and 10E, and a plurality of divided base materials 10A, 10B, and 10C connected by the joint parts 10D and 10E. Specifically, conductive ink is first pattern-printed on a surface of the base material 10 by any printing method described above, so that the circuits 20 having a plurality of conductor patterns (a plurality of lines illustrated in FIG. 1A) that linearly extend parallel to each other can be formed on the base material 10 (step (a) described below). As illustrated in FIG. 1A, a part of the circuits 20 arranged on an upper side may be denoted as a circuit 20A, and a part of the circuits 20 arranged on a lower side may be denoted as the circuit 20C when folded in step (c) described below. The number of conductor patterns that configure the circuits 20 (20A, 20C) is not limited, and one or more conductor patterns may be provided. The shape of the conductor patterns that configure the circuits 20 (20A, 20C) is not limited, and the conductor patterns may be freely formed.

Then, a part of the base material 10 may be punched out so that the base material 10 includes a plurality of divided base materials 10A, 10B, and 10C connected by the joint parts 10D and 10E (step (b) described below).

As illustrated in FIG. 1B, the base material 10 includes the divided base materials 10A, 10B, and 10C, and joint parts 10D and 10E. The joint part 10D connects the divided base material 10A and the divided base material 10B. The joint part 10E connects the divided base material 10B and the divided base material 10C. That is, the divided base materials 10A, 10B, and 10C are connected by the joint parts 10D and 10E.

Among the three divided base materials, the circuits 20 are formed on the divided base materials 10A and 10C. Specifically, a circuit 20A is formed on the divided base material 10A, and a circuit 20C is formed on the divided base material 10C. However, the circuits 20 are formed neither on the divided base material 10B nor on the joint parts 10D and 10E.

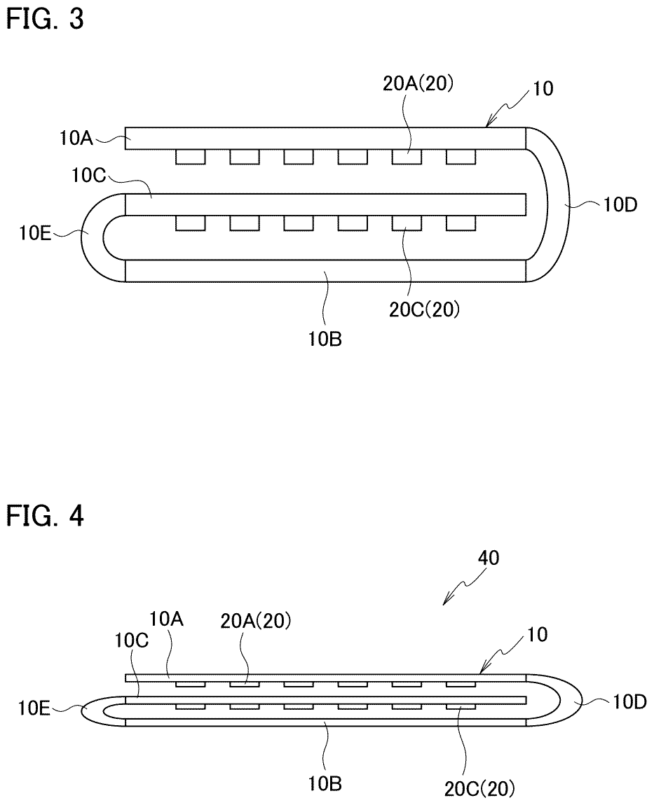

The joint parts 10D and 10E are folded, and at least parts of the circuits 20A and 20C printed on the plurality of divided base materials 10A and 10C may be layered in a vertical direction in a plan view. Specifically, as illustrated in FIG. 3, the joint parts 10D and 10E of the base material 10 are folded, with the surfaces on which the circuits 20 are printed facing the inside, and with a longitudinal direction of the base material 10 as an axis. Further, as illustrated in FIG. 4, the base material 10 is compressed and layered in the vertical direction by thermoforming or the like, to form the connection circuit 40 (step (c) described below).

In the connection circuit 40, the circuit 20A and the circuit 20C are layered in the vertical direction in a plan view, with the divided base material 10A arranged uppermost, as illustrated in FIG. 4 and FIG. 1C. Specifically, the divided base material 10A, the circuit 20A, the divided base material 10C, the circuit 20C, and the divided base material 10B are arranged in this order from the top, and the divided base material 10C is interposed between the circuit 20A and the circuit 20C in the vertical direction in a side view, as illustrated in FIG. 4. Further, the circuit 20A and the circuit 20C may be completely layered in the vertical direction, as illustrated by the dotted line in FIG. 1C. As described above, the circuit 20A and the circuit 20C are surrounded by the base material 10, so that the base material 10 functions as insulation coating of electric wires, thereby forming a bundle of electric wires in which the circuit 20A and the circuit 20C are insulated.

The connection circuit 40 is produced by a method in which the circuits 20 are first printed on the base material 10 with conductive ink, and then the base material 10 is folded and layered. Therefore, the connection circuit 40 can be easily produced with fewer manufacturing steps in spite of the multi-layered structure. Moreover, the degrees of freedom of circuit formation can be increased due to the multi-layered structure of connection circuit 40, so that it is possible to make the connection circuit thinner and lighter than conventional coated electric wires. Furthermore, the circuit 20A and the circuit 20C are layered one above the other across the divided base material 10C, so that the noise resistance of the connection circuit 40 can be improved.

As described above, the connection circuit 40 according to the present embodiment includes the base material 10 having electrical insulation properties, and the circuits 20 printed on the base material 10 with conductive ink. In the connection circuit 40, a part of the base material 10 is folded, and at least parts of the circuits 20 are layered in the vertical direction in a plan view; and the base material 10 is interposed between the circuits 20 in the vertical direction in a side view. Therefore, the connection circuit 40 can be simply produced using conductive ink, and it is possible to provide a connection circuit which increases the degrees of freedom of circuit formation and improves noise resistance.

### Method of Manufacturing a Connection Circuit

The method of manufacturing the connection circuit 40 according to the present embodiment provides a method of manufacturing the connection circuit 40 including the base material 10 having electrical insulation properties, and the circuits 20 printed on the base material 10 with conductive ink.

The method of manufacturing the connection circuit 40 according to the present embodiment includes a step (step (a)) of printing the circuits 20 on the base material 10 with conductive ink. Further, the method of manufacturing includes a step (step (b)) of punching out a part of the base material 10 so that the base material 10 includes joint parts, and a plurality of divided base materials connected by the joint parts. The method of manufacturing the connection circuit 40 includes a step (step (c)) of folding and arranging the joint parts so that at least parts of the circuits printed on the plurality of divided base materials are layered in the vertical direction in a plan view. Furthermore, the method of manufacturing the connection circuit 40 includes a step (step (c)) of interposing the base material 10 between the circuits 20 in the vertical direction in a side view. The steps will be described below.

### Step (a)

Step (a) is a step of printing the circuits 20 with conductive ink on the base material 10 having electrical insulation properties. The circuits 20 having a plurality of conductor patterns that linearly extend parallel to each other may be formed on the base material 10 by pattern printing of conductive ink on the surface of the base material 10, using the printing methods described above. As illustrated in FIG. 1A, as for the circuits 20, a part arranged on an upper side may be denoted as a circuit 20A, and a part arranged on a lower side may be denoted as the circuit 20C when folded in step (c) described below.

### Step (b)

Step (b) is a step of punching a part of the base material 10 so that the base material 10 includes joint parts 10D and 10E, and a plurality of divided base materials 10A, 10B, and 10C connected by joint parts 10D and 10E.

As illustrated in FIG. 1B, the base material 10 includes the divided base materials 10A, 10B, and 10C, and the joint parts 10D and 10E. The joint part 10D connects the divided base material 10A and the divided base material 10B. The joint part 10E connects the divided base material 10B and the divided base material 10C. That is, the divided base materials 10A, 10B, and 10C are connected by the joint parts 10D and 10E.

The circuits 20 are formed on the divided base materials 10A and 10C, among the three divided base materials. Specifically, the circuit 20A is formed on the divided base material 10A, and the circuit 20C is formed on the divided base material 10C. However, the circuits 20 are formed neither on the divided base material 10B nor on the joint parts 10D and 10E.

The method of punching a part of the base material 10 is not particularly limited, and any conventionally known method can be adopted. After being punched, the base material 10 may have punched portions 30, which extend in a longitudinal direction of the base material 10, and between which the joint parts 10D and 10E are located, as illustrated in FIG. 1B.

### Step (c)

Step (c) is a step of folding and arranging the joint parts 10D and 10E so that at least parts of the circuits 20A and 20C printed on the plurality of divided base materials 10A and 10C are layered in a vertical direction in a plan view. Further, step (c) is a step of interposing the base material 10 between the circuits 20 in the vertical direction in a side view. Specifically, as illustrated in FIG. 3, the joint parts 10D and 10E of the base material 10 are folded, with the surface on which the circuits 20 are printed facing the inside, and with the longitudinal direction of the base material 10 as an axis. Namely, the divided base material 10A, the circuit 20A, the divided base material 10C, the circuit 20C, and the divided base material 10B are arranged in this order from the top. At least parts of the circuits 20A and 20C printed on the plurality of divided base materials 10A and 10C, respectively, are arranged to be layered in the vertical direction in a plan view. Furthermore, the divided base material 10C is arranged to be interposed between the circuits 20A and 20C in the vertical direction in a side view. After being folded as illustrated in FIG. 3, the base material 10 is compressed and layered in the vertical direction by thermoforming or the like, to form the connection circuit 40, as illustrated in FIG. 4. The circuits 20A and 20C may be completely layered in the vertical direction, as illustrated by the dotted line in FIG. 1C. As described above, the circuits 20A and 20C are surrounded by the base material 10, so that the base material 10 functions as insulation coating of an electric wire, thereby the circuits 20A and 20C can form a bundle of electric wires that is electrically insulated.

The connection circuit 40 is produced by a method in which the circuits 20 are first printed on the base material 10 with conductive ink, and then the base material 10 is folded and layered. Therefore, the connection circuit 40 can be easily produced with fewer manufacturing steps in spite of the multi-layered structure. Moreover, due to the multi-layered structure of connection circuit 40, the degrees of freedoms of circuit formation can be increased, so that it is possible to make the connection circuit thinner and lighter than conventional coated electric wires. Furthermore, the circuit 20A and the circuit 20C are layered one above the other across the divided base material 10C, so that the noise resistance of the connection circuit 40 can be improved.

As described above, the method of manufacturing the connection circuit 40 according to the present embodiment provides a method of manufacturing a connection circuit including a base material having electrical insulation properties, and circuits printed on the base material with conductive ink. The manufacturing method includes a step of printing the circuits 20 on the base material 10 with conductive ink. Further, the manufacturing method includes a step of punching out a part of the base material 10 so that the base material 10 includes joint parts 10D and 10E, and a plurality of divided base materials 10A, 10B and 10C connected by the joint parts 10D and 10E. The manufacturing method includes a step of folding and arranging the joint parts 10D and 10E so that at least parts of the circuits 20A and 20C printed on the plurality of divided base materials 10A and 10C are layered in a vertical direction in a plan view. Further, the method of manufacturing the connection circuit 40 includes a step of interposing the base material 10 between the circuits 20 in the vertical direction in a side view. Therefore, the connection circuit 40 can be simply produced using conductive ink, and it is possible to provide a connection circuit which increases the degrees of freedom of circuit formation and improves noise resistance.

### Second Embodiment

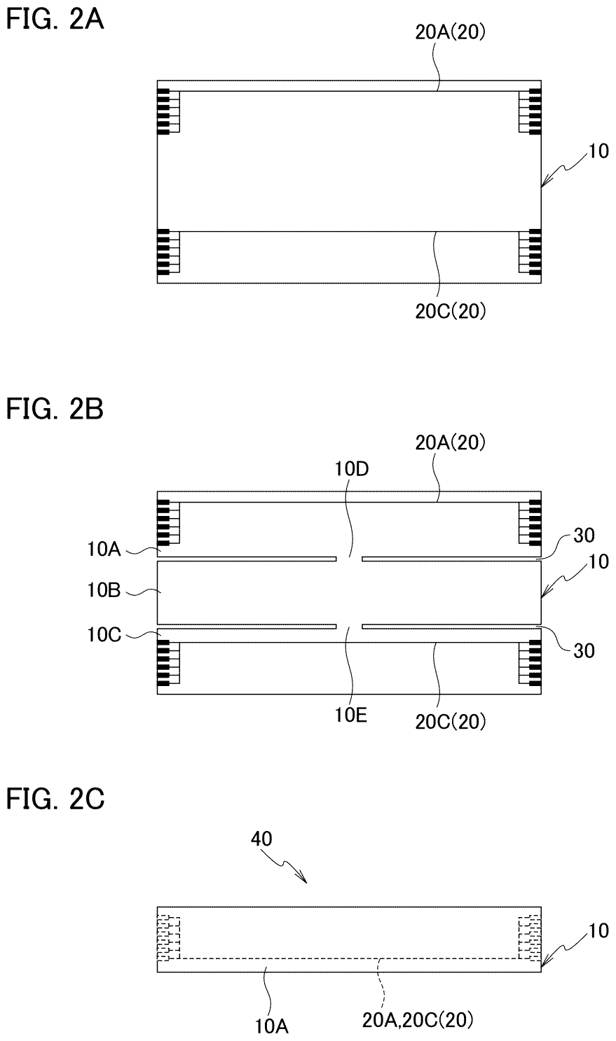

Next, the connection circuit 40 according to a second embodiment will be described with reference to FIGS. 2A to 2C. One or more patterns that configure the circuits 20 may have a joint structure capable of integrally connecting the conductor patterns. Specifically, as illustrated in FIG. 2A, conductive ink may be pattern-printed on the surface of the base material 10 by any printing method described above so that the one or more conductor patterns at both ends may be connected to a single conductor pattern at a center of the base material 10. The number of conductor patterns that configure the circuits 20 (20A, 20C) is not limited, and one or more conductor patterns may be provided. The shape of the conductor patterns that configures the circuits 20 (20A, 20C) is not limited, and the conductor patterns may be freely formed. Other parts are the same as those of the connection circuit 40 according to the first embodiment, and are not described in detail.

As illustrated in FIG. 2B, the base material 10 includes the divided base materials 10A, 10B, and 10C, and joint parts 10D and 10E. The divided base materials 10A, 10B, and 10C are connected by the joint parts 10D and 10E. The circuit 20A is formed on the divided base material 10A, and the circuit 20C is formed on the divided base material 10C. However, the circuits 20 are formed neither on the divided base material 10B nor on joint parts 10D and 10E.

As illustrated in FIG. 2C, the joint parts 10D and 10E are folded, and at least parts of the circuits 20A and 20C printed on the plurality of divided base materials 10A and 10C may be arranged to be layered in the vertical direction in a plan view. Specifically, as illustrated in FIG. 3, the joint parts 10D and 10E of the base material 10 are folded, with the surfaces on which the circuits 20 are printed facing the inside, and with a longitudinal direction of the base material 10 as an axis. Further, as illustrated in FIG. 4, the base material 10 is compressed and layered in the vertical direction by thermoforming or the like, to form the connection circuit 40.

In the connection circuit 40, the circuit 20A and the circuit 20C are layered in the vertical direction in a plan view with the divided base material 10A arranged uppermost, as illustrated in FIGS. 4 and 2C. Specifically, the divided base material 10A, the circuit 20A, the divided base material 10C, the circuit 20C and the divided base material 10B are arranged in this order from the top, and the divided base material 10C is interposed between the circuit 20A and the circuit 20C in the vertical direction in a side view, as illustrated in FIG. 4. Further, the circuit 20A and the circuit 20C may be completely layered in the vertical direction, as illustrated by dotted lines in FIG. 2C. As described above, the circuit 20A and the circuit 20C are surrounded by the base material 10, so that the base material 10 functions as insulation coating of electric wires, thereby forming a bundle of electric wires in which the circuit 20A and the circuit 20C are insulated.

The connection circuit 40 is produced by a method in which the circuits 20 are first printed on the base material 10 with conductive ink, and then the base material 10 is folded and layered. Therefore, the connection circuit 40 can be easily produced with fewer manufacturing steps in spite of the multi-layered structure. Moreover, the degrees of freedom of circuit formation can be increased due to the multi-layered structure of connection circuit 40, so that it is possible to make the connection circuit thinner and lighter than conventional coated electric wires. Furthermore, the circuit 20A and the circuit 20C are layered one above the other across the divided base material 10C, so that the noise resistance of the connection circuit 40 can be improved. Therefore, the connection circuit 40 can be simply produced using conductive ink, and it is possible to provide a connection circuit which increases the degrees of freedom of circuit formation and improves noise resistance.

### Third Embodiment

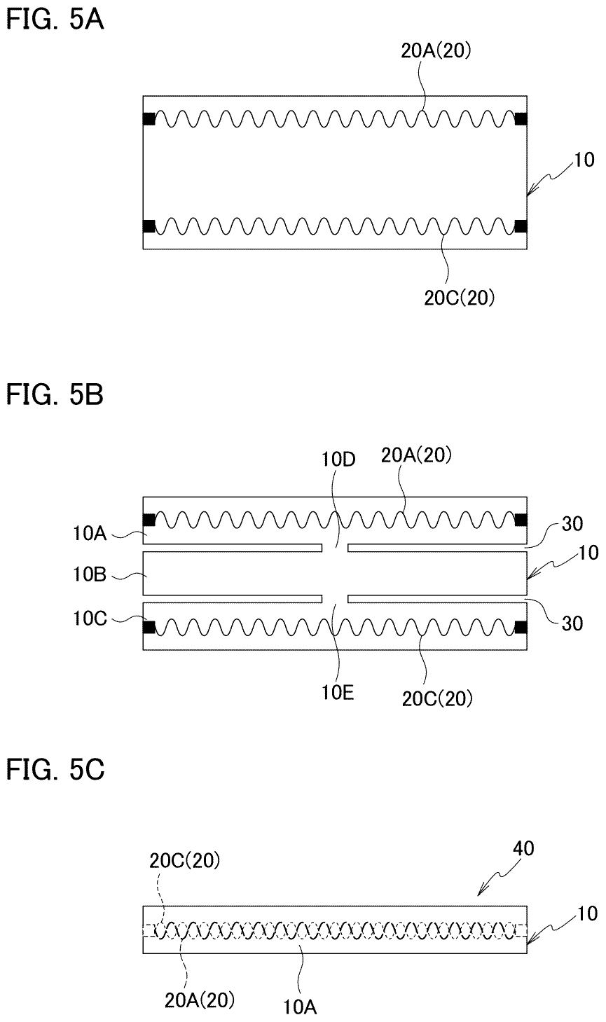

The connection circuit 40 according to the third embodiment will be described with reference to FIGS. 5A to 5C. The conductor pattern that configure the circuits 20 may have wavy lines. As illustrated in FIG. 5A, from the viewpoint of noise resistance, which will be described later, it is preferable that the wavy lines of the conductor patterns of the circuits 20A and 20C have the same pitch and amplitude. The number of conductor patterns that configure the circuits 20 (20A, 20C) is not limited, and one or more conductor patterns may be provided. The shape of the wavy lines of the conductor patterns that configure the circuit 20s (20A, 20C) is not limited, and can be freely formed. Other parts are the same as those of the connection circuit 40 according to the first embodiment, and are not described in detail.

As illustrated in FIG. 5B, the base material 10 includes the divided base materials 10A, 10B, and 10C, and joint parts 10D and 10E. The divided base materials 10A, 10B, and 10C are connected by the joint parts 10D and 10E. The circuit 20A is formed on the divided base material 10A, and the circuit 20C is formed on the divided base material 10C. However, the circuits 20 are formed neither on the divided base material 10B nor the joint parts 10D and 10E.

As illustrated in FIG. 5C, the joint parts 10D and 10E are folded, and at least parts of the circuits 20A and 20C printed on the plurality of divided base materials 10A and 10C may be arranged to be layered in the vertical direction in a plan view. Specifically, the joint parts 10D and 10E of the base material 10 are folded, with the surfaces on which the circuits 20 are printed facing the inside, and with a longitudinal direction of the base material 10 as an axis. Further, the base material 10 is compressed and layered in the vertical direction by thermoforming or the like, to form the connection circuit 40.

In the connection circuit 40, the circuit 20A and the circuit 20C are layered in the vertical direction in a plan view with the divided base material 10A arranged uppermost, as illustrated in FIG. 5C, and the divided base material 10C is interposed between the circuits 20A and 20C in a side view. The circuit 20A and the circuit 20C are surrounded by the base material 10, so that the base material 10 functions as insulation coating of electric wires, thereby forming a bundle of electric wires in which the circuit 20A and the circuit 20C are insulated.

When the wavy lines of the conductor patterns of the circuits 20A and 20C have the same pitch and amplitude, it is preferable that the positions of the peaks and valleys of the two wavy lines of the conductor patterns are reversed in a plan view, as illustrated in FIG. 5C. When the conductor patterns of the circuits 20A and 20C are formed in this manner, the currents flowing through the circuits 20A and 20C cancel each other's magnetic fields, so that noise resistance can be improved in the same manner as a twisted pair cable. The twisted pair cable is a structure in which two electric wires are twisted in a spiral shape, and is known as a cable with high noise shielding.

The connection circuit 40 is produced by a method in which the circuits 20 are first printed on the base material 10 with conductive ink, and then the base material 10 is folded and layered. Therefore, the connection circuit 40 can be easily produced with fewer manufacturing steps in spite of the multi-layered structure. Moreover, due to the multi-layered structure of connection circuit 40, the degrees of freedom of circuit formation can be increased, so that it is possible to make the connection circuit thinner and lighter than conventional coated electric wires. Furthermore, the circuit 20A and the circuit 20C are layered one above the other across the divided base material 10C, the noise resistance of the connection circuit 40 can be improved by reversing the positions of the peaks and valleys of the wavy lines of the conductor pattern in a plan view. Therefore, the connection circuit 40 can be simply produced using conductive ink, and it is possible to provide a connection circuit which increases the degrees of freedom of circuit formation and improves noise resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A connection circuit comprising:
a base material having electrical insulation properties; and
circuits printed on the base material with conductive ink; wherein:
a part of the base material is folded, and at least parts of the circuits are layered in a vertical direction in a plan view; and
the base material is interposed between the circuits in the vertical direction in a side view.

2. The connection circuit according to claim 1, wherein:
the base material comprises joint parts, and a plurality of divided base materials connected by the joint parts; and
the joint parts are folded, and at least parts of circuits printed on the plurality of divided base materials are layered in a vertical direction in a plan view.

3. The connection circuit according to claim 1, wherein conductor patterns that configure the circuit have a joint structure.

4. The connection circuit according to claim 1, wherein conductor patterns that configure the circuit have a wavy line.

5. A method of manufacturing a connection circuit comprising a base material having electrical insulation properties, and circuits printed on the base material with conductive ink, comprising:
a step of printing circuits on the base material with conductive ink;
a step of punching out a part of the base material so that the base material comprises joint parts, and a plurality of divided base materials connected by the joint parts; and
a step of folding and arranging the joint parts so that at least parts of circuits printed on the plurality of divided base materials are layered in a vertical direction in a plan view, and interposing the base material between the circuits in the vertical direction in a side view.
